(19) United States
(12) Patent Application Publication
(10) Pub. No.: US 2013/0286742 A1
(43) Pub. Date: Oct. 31, 2013

(54) SEMICONDUCTOR MEMORY DEVICE AND TEST METHOD OF THE SAME

(71) Applicant: KABUSHIKI KAISHA TOSHIBA, Tokyo (JP)

(72) Inventors: Yuji KOMINE, Hino-shi (JP); Mitsuhiro KOGA, Miura-gun (JP); Yukio KOMATSU, Yokohama-shi (JP); Tomonari IWASAKI, Tokyo (JP)

(73) Assignee: KABUSHIKI KAISHA TOSHIBA, Tokyo (JP)

(21) Appl. No.: 13/802,605

(22) Filed: Mar. 13, 2013

(30) Foreign Application Priority Data
Apr. 26, 2012 (JP) 2012-101745

(51) Int. Cl. G11C 16/34

(52) U.S. Cl. CPC G11C 16/3459
USPC 365/185.19

(57) ABSTRACT

According to one embodiment, a semiconductor memory device includes a memory cell array includes memory cells and a word line coupling the memory cells. A determination circuit determines whether write to a first memory cell group of the word line succeeded, and whether write to a second memory cell group of the word line succeeded. A test circuit counts application of write voltage during write to the word line, compares with a threshold a difference between a count of write voltage application upon success of one of respective writes to the first and second memory cell groups and a count of write voltage application upon success of the other of respective the writes, and outputs a result of the comparison.

### CROSS-REFERENCE TO RELATED APPLICATIONS

This application is based upon and claims the benefit of priority from Japanese Patent Application No. 2012-101745, filed Apr. 26, 2012, the entire contents of which are incorporated herein by reference.

### FIELD

Embodiments described herein relate generally to a semiconductor memory device and a method for testing the same.

### BACKGROUND

As NAND flash memories continue to become smaller, defects due to word lines increase. Specifically, a write property varies among the word lines to result in a deteriorated write performance of the memories. In order to detect defects due to the word lines, various screening tests are performed at a die sort stage.

### BRIEF DESCRIPTION OF THE DRAWINGS

FIG. 1 illustrates an example state in a screening test.

FIG. 2 illustrates an example screening test flow.

FIG. 3 illustrates an example state in the screening test.

FIG. 4 illustrates a block diagram of a semiconductor memory device according to a first embodiment.

FIG. 5 illustrates an example circuit diagram of a block.

FIG. 6 illustrates an example sectional view of a block.

FIG. 7 illustrates a block diagram of part of the semiconductor memory devices according to the first embodiment.

FIG. 8 illustrates a state in a screening test according to the first embodiment.

FIG. 9 illustrates the flow of part of the screening test of the first embodiment.

FIG. 10 illustrates a state in the screening test according to the first embodiment.

FIG. 11 illustrates the flow of another part of the screening test of the first embodiment.

FIG. 12 illustrates an example case in the screening test of the first embodiment.

FIG. 13 illustrates another example case in the screening test of the first embodiment.

FIG. 14 illustrates still another example case in the screening test of the first embodiment.

FIG. 15 illustrates a block diagram of part of a semiconductor memory device according to a second embodiment.

FIG. 16 illustrates the flow of part of a screening test of the second embodiment.

FIG. 17 illustrates the flow of another part of the screening test of the second embodiment.

### DETAILED DESCRIPTION

In general, according to one embodiment, a semiconductor memory device includes a memory cell array comprising memory cells and a word line coupling the memory cells. A determination circuit determines whether write to a first memory cell group of the word line succeeded, and whether write to a second memory cell group of the word line succeeded. The first memory cell group is different from the second memory cell group. A test circuit is configured to count application of write voltage during a write to the word line, compare with a threshold a difference between a count of write voltage application upon success of one of a write to the first memory cell group and a write to the second memory cell group and a count of write voltage application upon success of the other of a write to the first memory cell group and a write to the second memory cell group, and output a result of the comparison.

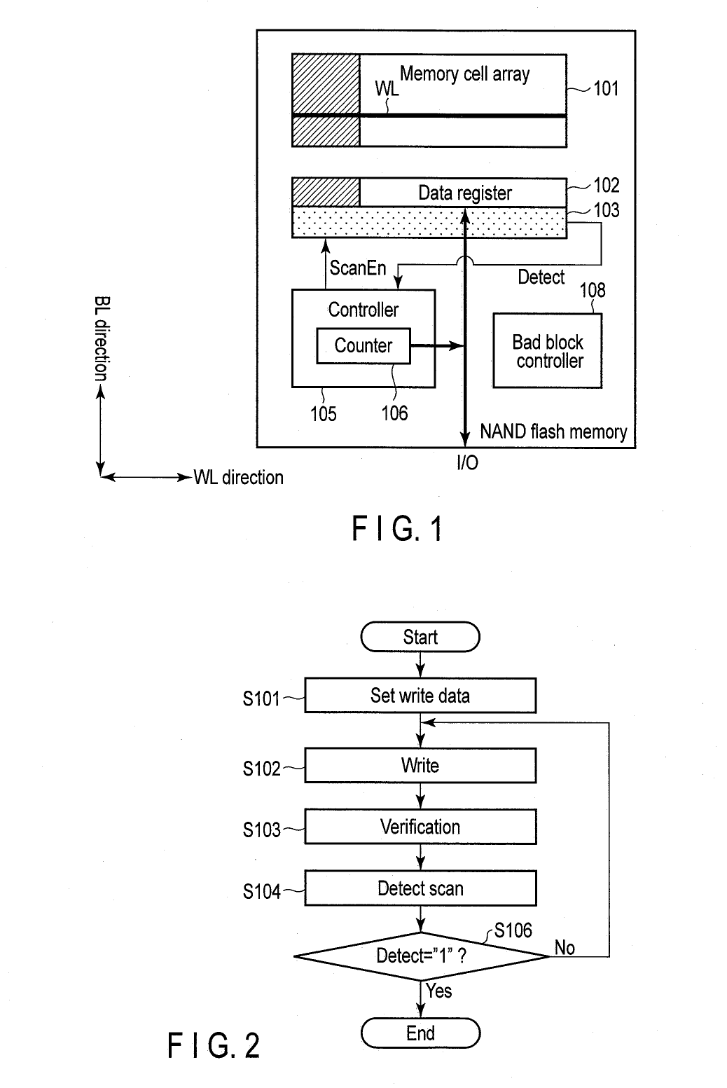

Progress in shrinking of memory cells is making unintentional thinning of part of a word line (or word line thinning) more problematic. The inventors have obtained the following findings in the process of development of embodiments. FIG. 1 illustrates an example state in a screening test to detect memories with thinned word lines. FIG. 2 illustrates the flow of the screening test. In the memory cell array 101, word lines WL extend along the word line direction and are arranged along the bit line direction. A row decoder (not shown) to apply voltages to the word lines is arranged at one end thereof, such as their left-hand side. First, write to a particular number of memory cells coupled to a to-be-tested word line WL at one end thereof, such as its left-hand side, is tested. Specifically, write to a particular number of bits on the left-hand side of the to-be-tested page, which are indicated with shade, are tested. First, write data is supplied to the NAND flash memory from a tester device through an I/O (step S101). The write data is then written in the test target page in the memory cell array 101 (step S102). No data is written in bits other than the test target bits. Verification is then executed (step S103). In the verification, upon success of data write to a bit, a latch circuit for that bit in a data register 102 stores a value indicative of the completion of the write as first data. A latch circuit for a bit to which no data is written can originally store a value indicative of write completion as the first data. A detect scan is then executed (step S104). In step S104, a determination circuit 103 checks the data register 102 to determine whether the number of pieces of first data indicative of write completion is greater than or equal to a threshold (step S106). When the determination indicates Yes, the determination circuit 103 then determines the to-be-tested page as a pass, and outputs a signal Detect. The write, verification, and detect scan are repeated, and the number of such a loop is counted and stored by a counter 106. The second or further writes may be referred to as “additional write”, which can involve write with a voltage greater than that for the previous write (or write voltage reapplication). If the determination in step S106 indicates Yes, the value currently stored in the counter 106 is then output to the tester device through the I/O. The tester device stores the received value. If the determination in step S106 is No, a new loop (or additional write) is then repeated from step S101.

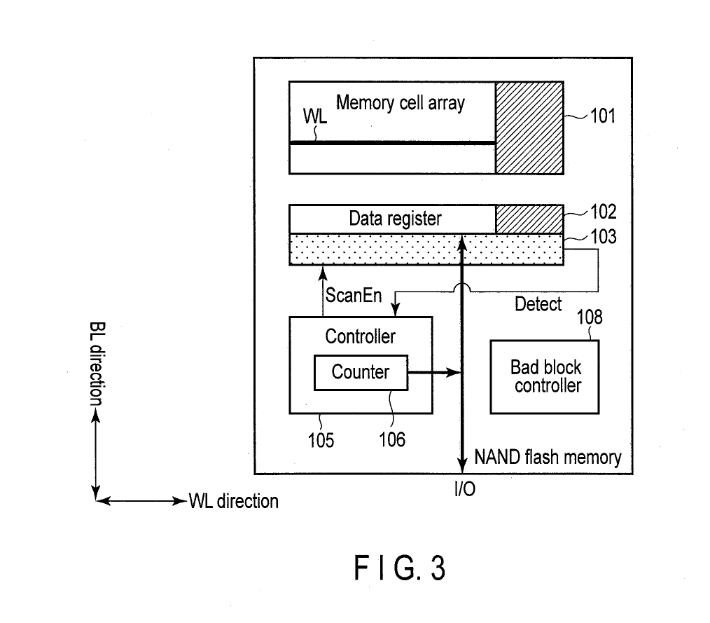

Write to a particular number of bits on the right-hand side of the to-be-tested page, which are indicated with shade, are tested as shown in FIG. 3. Its details are the same as those for the test to the left-hand side bits (see FIG. 2). The count of loops taken for the to-be-tested page to pass is output to the tester device from the counter 106. The tester device stores the received value. The tester device calculates the difference of the loop count for the first data for the left-hand side, and that for the right-hand side. When the calculated difference exceeds a threshold, the tester determines the word line to be tested is defective due to the word line thinning, or disconnect defect. A block including a word line determined to have the disconnect defect is classified as a bad block. The classification as a bad block may be performed by the tester specifying its address to a bad block controller 108. The above process is executed to all the word lines WL.

The example technique of FIGS. 1 to 3 can be used to find disconnect defects effectively. Specifically, it is possible to obtain the difference between the respective write loop counts for memory cell sets at the near and far sides to and from the row decoder to perform simplified determination that a to-be-tested word line is unintentionally thin.

The FIGS. 1 to 3 example, however, requires two writes to each word line WL. It also involves outputting two loop-counts for each word line WL and processing them by the tester device. As described above, there are a number of word lines WL as a result of increase in a memory capacity. This results in an increased time necessary for the test.

Embodiments will now be described with reference to figures. Components with substantially the same functionalities and configurations will be referred to with the same reference number and duplicate descriptions will be made only when required. The embodiments only illustrate devices and methods which embody their technical idea, which do not limit the material, dimension, structure, and arrangement of components to the following ones. The technical idea of the embodiments may be variously changed in accordance with the scope of the claims.

Functional blocks do not need be distinguished as shown in the figures. For example, some of the functions may be performed by functional blocks different from those illustrated below. Moreover, an illustrated functional block may be divided into functional sub-blocks. The embodiments are not limited by the specification of the particular functional blocks.

### First Embodiment

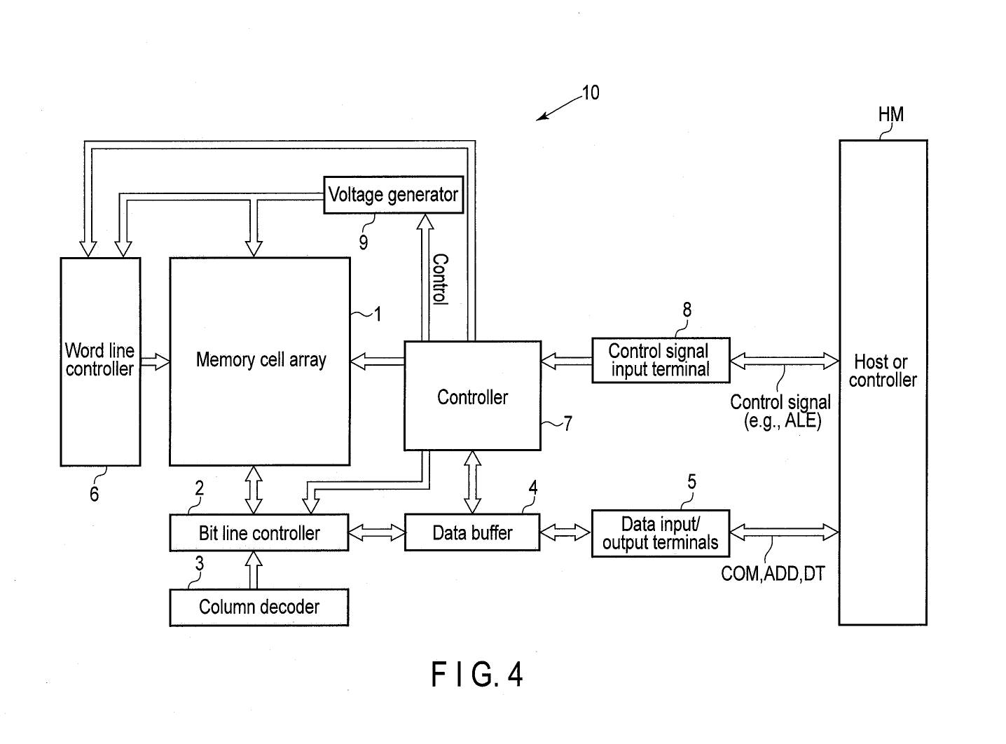

FIG. 4 illustrates a block diagram of a semiconductor memory device according to the first embodiment. As shown in FIG. 4, the semiconductor memory device (NAND flash memory) 10 includes a memory cell array 1, a bit line controller 2, a column decoder 3, a data buffer 4, data input/output terminals 5, a word line controller 6, a controller 7, a control signal input terminal 8, and a voltage generator 9. The memory cell array 1 includes blocks. Each block includes components such as memory cells, word lines, and bit lines. A block includes pages each including or consisting of memory cells, and will be described in full detail later. The memory cell array 1 is electrically coupled to the bit line controller 2, word line controller 6, controller 7, and voltage generator 9.

As used herein, the term “to be coupled” (and grammatical variants thereof) is herein used in broad sense. The term “to be coupled” can include to be physically coupled and to be electrically coupled, as well as to be coupled with intervening conductor.

The bit line controller 2 reads data in the memory cells in the memory cell array 1 via the bit lines, and senses the state of the memory cells via the bit lines. The bit line controller 2 also applies write voltage (or program voltage) to the memory cells in the memory cell array 1 via the bit lines to write (or program) data in the memory cells. The column decoder 3, data buffer 4, and controller 7 are electrically coupled to the bit line controller 2.

The bit line controller 2 includes components such as a sense amplifier, and data storage circuits (not shown). A particular data storage circuit is selected by the column decoder 3. Data in the memory cells read to the selected data storage circuit is output to outside the memory from the data input/output terminals 5 via the data buffer 4. The data input/output terminals 5 are coupled to a device outside the memory such as a host or a memory controller. The data input/output terminals 5 receive various commands COM and addresses ADD, which control the operation of the semiconductor memory device 10, from the host or memory controller HM, receives data DT, and outputs data DT to the host or memory controller HM. Write data DT received by the data input/output terminals 5 is supplied via the data buffer 4 to a data storage circuit selected by the column decoder 3. The commands COM and addresses ADD are supplied to the controller 7. The sense amplifier amplifies the potential of the bit lines.

The word line controller 6 selects a particular word line in the memory cell array 1 in accordance with the control by the controller 7. The word line controller 6 receives from the voltage generator 9 voltages for read, write, or erase. The word line controller 6 applies received voltages to the selected word line.

The controller 7 is electrically coupled to the memory cell array 1, bit line controller 2, column decoder 3, data buffer 4, word line controller 6, and voltage generator 9 to control them. The controller 7 is coupled to the control signal input terminal 8, and is controlled by control signals such as an address latch enable (ALE) signal received from outside via the control signal input terminal 8. The controller 7 outputs control signals to the voltage generator 9 to control the voltage generator 9.

The voltage generator 9 gives components such as the memory cell array 1 and word line controller 6 voltages for operation such as write, read and erase in accordance with the control by the controller 7. The voltage generator 9 is configured to generate such various voltages. Specifically, the voltage generator 9 generates voltage VREAD in data read, voltage VPGM, VPASS and VISO in data write, or voltage VERA in data erase, for example.

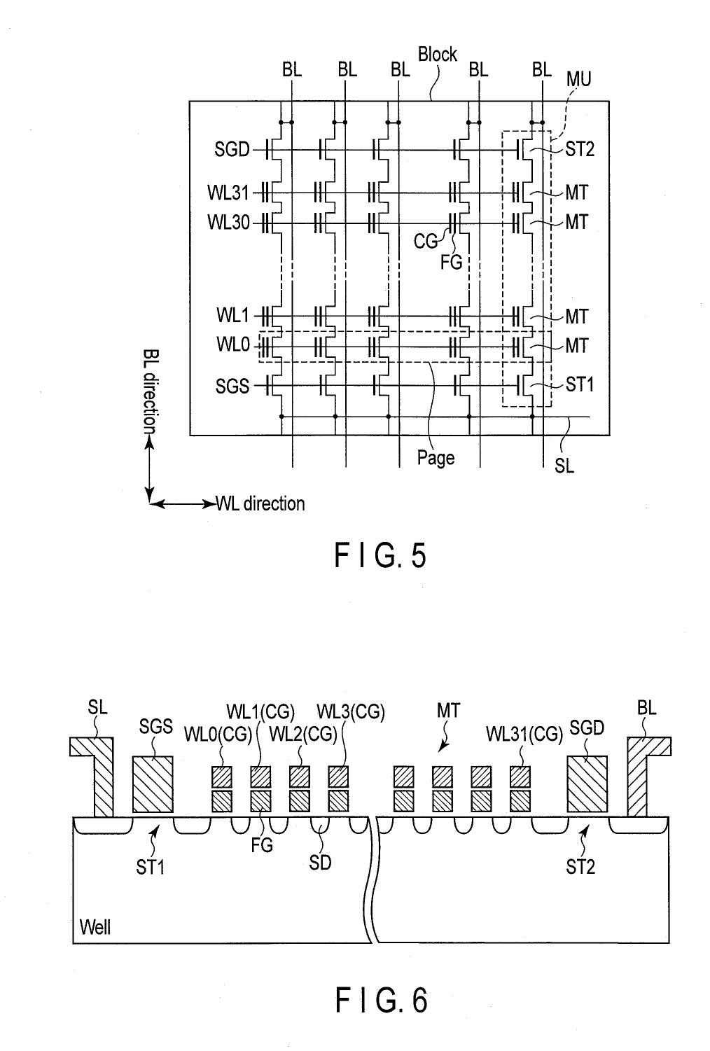

FIGS. 5 and 6 illustrate a circuit diagram and a sectional view of an example block Block, respectively. FIG. 5 describes only one block Block. As shown in FIGS. 5 and 6, the block Block includes memory cell columns (or memory cell units) MU arranged along the word line direction (WL_direction). The memory cell columns MU extend along the bit line direction (BL_direction). Each memory cell column MU includes or consists of a NAND string and select transistors ST1 and ST2. A NAND string includes or consists of memory cell transistors (for example, 32 cell transistors) MT whose current paths (or source/drains SD) are mutually coupled in series. The select transistors ST1 and ST2 are coupled to both ends of the NAND string, respectively. The other end of the current path of the select transistor ST2 is coupled to a particular bit line BL, and the other end of the current path of the select transistor ST1 is coupled to the source line SL.

The word lines WL0 to WL31 extend along the WL direction, and are coupled to respective sets of memory cell transistors MT belonging to the same row. The select gate line SGD extends along the WL direction, and is coupled to all the select transistors ST2 in a block. The select gate line SGS extends along the WL direction, and is couple to all the select transistors ST1 in a block.

A set of memory cell transistors MT coupled to the same word line WL configure a page. Data is read and written per page. For a case of multiple-level memory cells each able to store data of two or more bits, two or more pages are assigned to one word line. Data erase is executed per block.

The memory cells MT are provided in respective intersections of the bit lines BL and word lines WL. The memory cells MT are provided on a well formed in a semiconductor substrate. Each memory cell MT has a tunnel insulator (not shown), a charge storage layer FG such as a floating gate electrode, an insulator which has traps or lamination thereof, an intermediate insulator (not shown), a control electrode (control gate electrode) CG (word line WL) stacked on the well, and source/drain areas SD. A source/drain area SD, which is part of a current path of a memory cells MT, is serially connected to a source/drain area SD of an adjacent memory cell MT. The select transistors ST1 and ST2 each include a gate insulator (not shown) and a gate electrode SGS or SGD stacked on the semiconductor substrate, and source/drain areas SD.

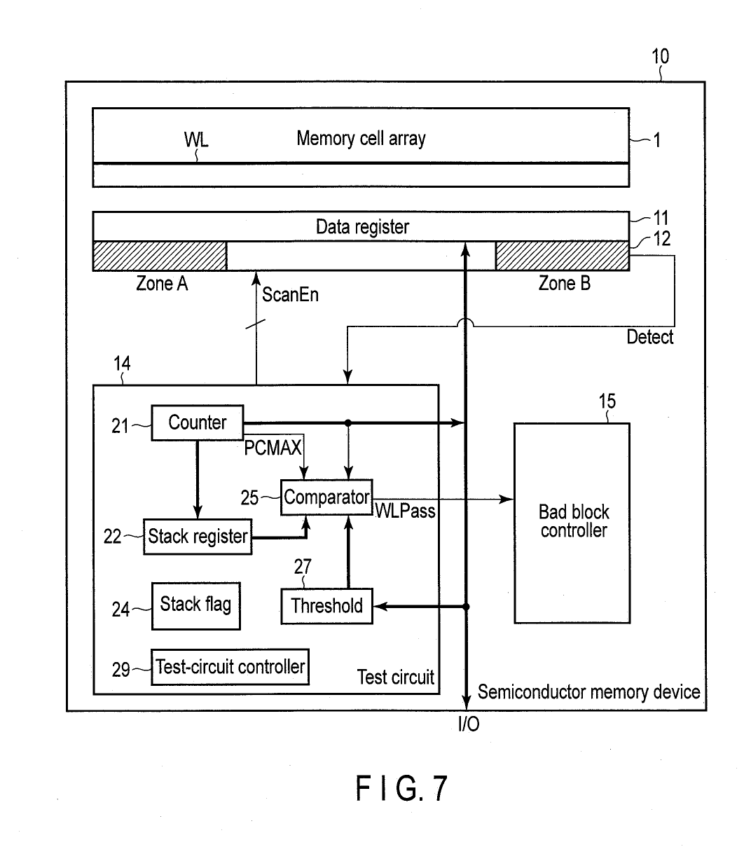

FIG. 7 illustrates a block diagram of part of the semiconductor memory device according to the first embodiment. Specifically, FIG. 7 shows part of the semiconductor memory device regarding the screening test to detect memories with a defect due to the word line thinning (or disconnect defect). As shown in FIG. 7, the semiconductor memory device 10 includes a memory cell array 1, a data register 11, a determination circuit 12, a test circuit 14, and a bad block controller 15. The data register 11 corresponds to part of, for example, the bit line controller 2 in FIG. 4. The determination circuit 12, test circuit 14, and bad block controller 15 correspond to part of function of, for example, the controller 7 in FIG. 4. The test circuit 14 includes a counter 21, a stack register 22, a stack flag holder 24, a comparator 25, a threshold register 27, and a test-circuit controller 29. The counter 21, stack register 22, stack flag holder 24, comparator 25, and threshold register 27 are included in the controller 7 in FIG. 4. The test-circuit controller 29 may be arranged outside the semiconductor memory device 10 such as within a memory tester. The stack flag holder 24 may be a register. The counter 21 can be implemented as a register for counting and storing the count (or loop count) of application of write voltage in ordinary write. The bus I/O in the figure corresponds to the data input/output terminals 5 and data buffer 4 in FIG. 4.

The data register 11 stores data of one-page size, and stores data for memory cells which configure a page in its respective register circuits. A page herein refers to memory cells which are read or written in one write or read operation. For example, a page includes or consists of memory cells coupled to one word line. The determination circuit 12 determines whether data items written in all or some of respective memory cells coupled to a to-be-tested word line WL (i.e., one-page size data) are a pass or a fail, which is referred to as a detect scan. Specifically, the determination circuit 12 determines whether data was successfully written to a page being written. More specifically, the determination circuit 12 determines whether the count of all bits in one page into which data was successfully written is greater than or equal to a threshold, and if this determination is Yes, it outputs a signal Detect (of “1”, for example). The threshold can be equal to the number of all or some of the to-be-tested memory cells in one page. The details of the determination are as follows. The latch circuits in the data register for respective bits into which the data is written store 0, the latch circuits for respective bits into which no data is written store 1. Write to the page is then executed and “1” is overwritten to latch circuits in the data register 11 for respective bits into which the data was successfully written. The determination circuit 12 determines whether the count of “1”-holding latches in the data register 11 is greater than or equal to a threshold.

The determination circuit 12 executes the determination to part of data in the data register 11 specified by signal ScanEn. Signal ScanEn specifies all the bits (or memory cells) of one page, initial some successive bits, or the last some successive bits. In the following description, initial successive memory cells and last successive memory cells in each page are referred to as zone A and zone B, respectively. Each of zones A and B is about 10% of the memory cells in a page, for example. It, however, may be a rate other than 10%, and the sizes of zones A and B may differ. Signal ScanEn also instructs the determination circuit 12 to start a detect scan. When zone A or B includes only a few memory cells, such as around the number of memory cells correctable with the ECC, then it makes the determination of the disconnect defect difficult. It is because the memory cells in zone A or B may pass or fail because of reasons other than the disconnect defect. On the other hand, with zone A or B occupying a majority of memory cells of one page, it reduces the size of an area from which a disconnect defect is detected, or the area between zones A and B. Therefore, each of zones A and B is desired to be about 10% of the number of memory cells in one page, for example.

In the semiconductor memory device 10, one write (or write to a particular page) involves two or more set of write voltage application. The counter 21 counts the set of write voltage application (or loop count) in the write and stores the count. When one of zones A and B for a page under test passes earlier than the other, the stack register 22 copies the current loop count from the counter 21 and stores it. The stack flag holder (or flag) 24 holds 0 at first, and holds 1 when the stack register 22 stores the value from the counter 21. The counter 21 also outputs a signal PCMAX when the loop count in one write exceeds the maximum. The output of PCMAX terminates the write sequence.

The comparator 25 calculates the difference of the value in the stack register 22, and the current loop count in the counter 21. Specifically, for a case of zone A passing earlier, the comparator 25 calculates the difference of the loop count in the stack register 22 stored when zone A passes, and the loop count in the counter 21 stored when zone B passes. The comparator 25 also compares the loop count difference with a threshold in the threshold register 27. When the difference exceeds the threshold, the comparator 25 outputs a signal WLPass indicative of fail (for example, 0) to the bad block controller 15. In contrast, when the loop count difference is less than or equal to the threshold, it outputs signal WLPass indicative of pass (for example, 1) to the bad block controller 15. The value in the threshold register 27 can be set to any value from outside the semiconductor memory device 10. The test-circuit controller 29 controls the operation of the whole test circuit 12.

Signal WLPass is supplied to the bad block controller 15. Upon output of signal WLPass indicative of the fail, the test-circuit controller 29 supplies the address specifying the page under test or failed page (or the address of the word line WL) to the bad block controller 15. The supplied address may be the address of the block including such the failed word line WL. When the bad block controller 15 receives signal WLPass with indicative of the fail, it registers the block including the failed word line WL as a bad block. Blocks registered as bad are not used by the semiconductor memory device 10. The bad block registration is implemented, for example by excluding the had block from a free block table.

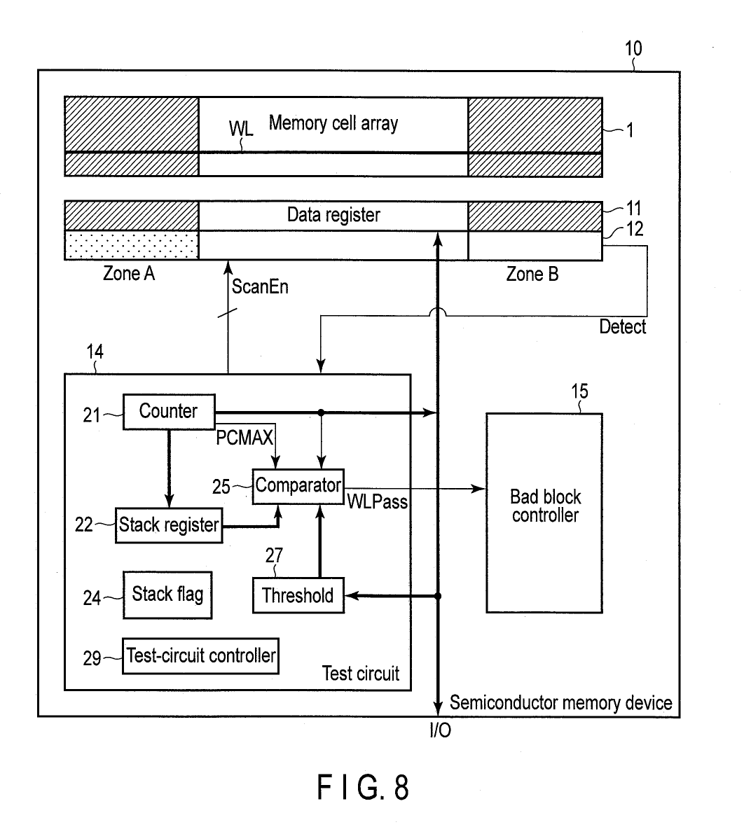

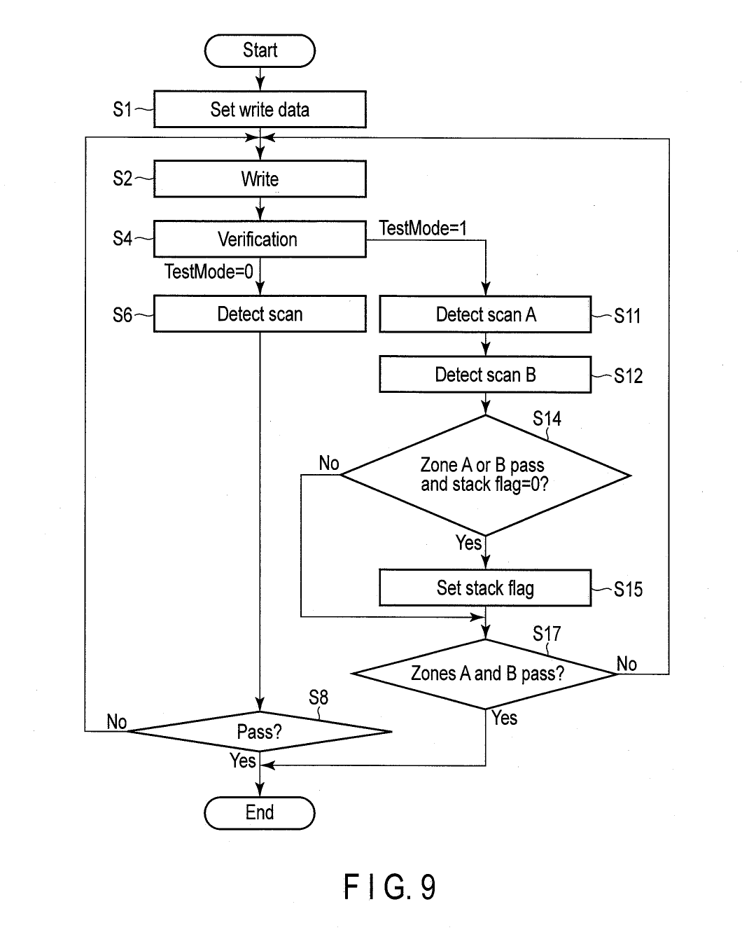

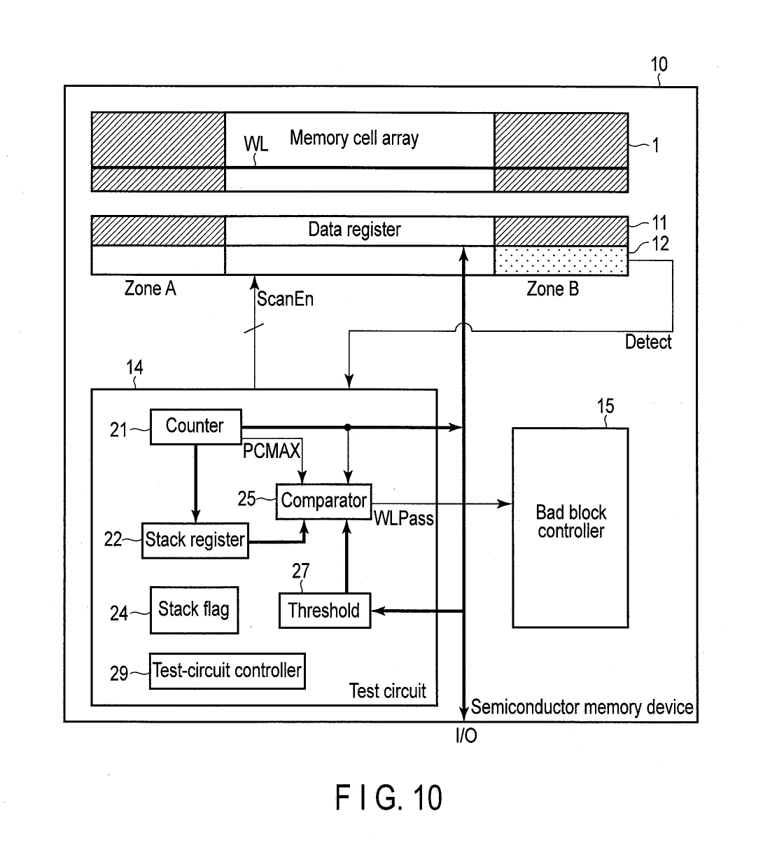

Referring now to FIGS. 8 to 10, the screening test in the semiconductor memory device according to the first embodiment will be described. FIGS. 8 and 10 each illustrate a state in the screening test according to the first embodiment. FIG. 9 illustrates the flow of the screening test (or write sequence) of the semiconductor memory device of the first embodiment. FIG. 9 illustrates the flow for one page.

The screening test includes various test modes. For example, a screening test for ordinary write defects is referred to as test mode 0. A screening test for disconnect defects is referred to as test mode 1.

First, a to-be-tested page (or word line WL), i.e., a write target page is specified from, for example, outside the semiconductor memory device 10 such as a tester. Then, as shown in FIGS. 8 and 9, write data is stored in the data register 11 (step S1). With test mode 0, the controller 7 controls the word line controller 6, bit line controller 2, and voltage generator 9 to write the write data in all the memory cells. With test mode 1, the controller 7 controls the word line controller 6, bit line controller 2, and voltage generator 9 to write the write data simultaneously in both zones A and B. The simultaneous write refers to write in zones A and B of memory cells coupled to a particular word line. Therefore, write data has bit values different from those for a unwritten state in both zones A and B, such as 0. Latch circuits other than those for zones A and B in the data register 11 store a unwritten state bit such as 1. The write data may be supplied from outside the semiconductor memory device 10, or generated by the test circuit 14 (for example, the test-circuit controller 29). The write data in the data register 11 is then written into the to-be-tested page (step S2). As described above, the data is written into zones A and B with one write. This is contrastive to two writes in the FIGS. 1 to 3 example.

Verification is then executed in step S4. Specifically, the controller 7 controls the word line controller 6, bit line controller 2, and voltage generator 9 to read the data from the last written page. The value held in each latch circuit in the data register 11 for a bit into which data was successfully written is overwritten with a value indicative of write completion (for example, 1). That is, latch circuits in the data register 11 for respective bits into which the data was successfully written are to hold a value of write completion (for example, 1).

Signal ScanEn is then supplied to the determination circuit 12 to start the detect scan. With signal ScanEn specifying test mode 0, the process shifts to step S6. Step S6 is the same as step S104 of FIG. 2. In step S6, the determination circuit 12 executes the detect scan to the whole data register 11. Specifically, the determination circuit 12 counts the 1 data holding ones of all the latch circuits in the data register 11. The determination circuit 12 then determines whether the to-be-tested page is a pass or fail (step S8).

With step S8 entered from step S6, the determination circuit 12 performs the determination as determining whether the total counted in step S6 is greater than or equal to a threshold. The threshold may be less than or equal to the number of all the latch circuits in the data register 11, which result in determination on whether all the latch circuits store 1 data. With the count greater than or equal to the threshold, the determination is a pass and the write sequence terminates. In contrast, with the count below the threshold, the determination is a fail and the process returns to step S2.

With signal ScanEn specifying test mode 1, the sequence shifts to step S11. When signal ScanEn specifies test mode 1, it can further specify zone A or B. FIG. 9 illustrates an example with zone A specified. In step S11, the determination circuit 12 executes the detect scan on zone A as shown in FIG. 8. Specifically, it compares the count in the data register 11 for zone-A memory cells with 1 data with a threshold. This threshold may be less than or equal to the number of all the memory cells included in zone A. If the determination is a pass, the determination circuit 12 supplies a signal Detect to the test circuit 14.

The sequence then shifts to step S12, where the determination, circuit 12 executes the detect scan on zone B as shown in FIG. 10. Its details are the same as those for step S11 with a different target to be determined. When the determination is a pass, the determination circuit 12 supplies signal Detect to the test circuit 14. The determination on zone B may be executed first in contrast to FIG. 9.

The process then shifts to step S14. In step S14, the test circuit 14 (for example, test-circuit controller 29) determines whether either zone A or B is a pass and the stack flag 24 is clear (for example, 0). When the determination is No, this indicates either zone A or B has already passed in a preceding loop. Alternatively, the determination No indicates zone A or B has not passed. With the determination No, the sequence shifts to step S17. In step S17, the test-circuit controller 29 determines whether both zones A and B have passed. The determination is executed by, for example, the test-circuit controller 29 storing reception of the Detect signal for each of zones A and B in a latch circuit. The determination Yes terminates the program sequence. The determination No indicates both zones A and B have not yet passed, and therefore the process returns to step S2. In step S2 entered through step S17, i.e., in rewrite voltage application, additional write is not executed to zone A or B which has passed earlier. In steps S11 and S12 after step S17, the determination circuit 12 skips the detect scan, but only uses the former result to output signal Detect.

In contrast, the determination Yes in step S14 indicates both zones A and B have passed simultaneously in the current loop, or either zone A or B has passed in the current loop with the other not having passed yet. When the determination is Yes, the sequence shifts to step S15. In step S15, the test circuit 14 copies the current loop count to the stack register 22 from the counter 21 and sets (or validates) the stack flag 24, for example through control of the test-circuit controller 29. The sequence then shifts to step S17.

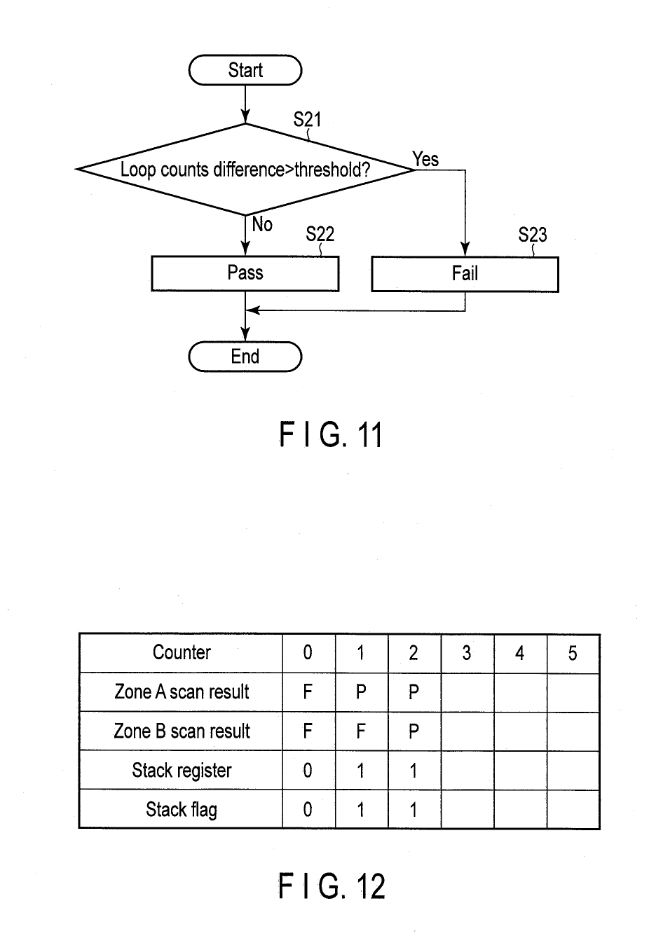

In the test mode 1, the write sequence of FIG. 9 continues to the flow of FIG. 11. FIG. 11 illustrates the flow of the screening test of the semiconductor memory device according to the first embodiment. As shown in FIG. 11, in step S21, the difference between the value in the stack register 22 and the current loop count in the counter 21 is calculated through control of the test-circuit controller 29. When the loop count difference is less than or equal to a threshold stored in the threshold register 27, the comparator 25 outputs a signal WLPass with a value indicative of a pass (for example, 1) (step S22). In contrast, when the loop count difference exceeds the threshold, the comparator 25 outputs signal WLPass with a value indicative of fail (for example, 0) (step S23). Even with the determination Yes in step S21, when signal PCMAX is 1, i.e., step S21 has been entered after the write terminates with fail, the flow also shifts to step S23. The screening test for the disconnect defect (test mode 1) can follow the Lest for write defect (test mode 0) as described above. As a result, PCMAX does not become 1 at the stage of the screening test for the disconnect defect. This can simplify the screening test for the disconnect defect.

Signal WLPass with the fail value output in step S23 is received by the bad block controller 15. The bad block controller 15 registers as bad (or, bad-blockizes) the block including the page under test. The address of the page under test is known by the test circuit 14, and is supplied to a component such as the bad block controller 15 from the test-circuit controller 29. The registration as a bad block may be executed as part of the FIGS. 9 and 11 flow, or executed after the FIG. 11 flow by a command from the tester device.

FIGS. 12 to 14 illustrate various cases in the screening test according to the first embodiment. The row of “counter” indicates loop counts. Note that zero corresponds to the first loop. FIGS. 12 to 14 relate to an example case of value 2 in the threshold register 27.

FIG. 12 illustrates a case where both zones A and B pass and the difference between the loop count for zone A to pass and that for zone B to pass is below a threshold. As shown in FIG. 12, neither zone A nor zone B passes in the first loop. Zone A passes in the second loop. This results in storing the value in the counter 21 (i.e., 1) in the stack register 22 and setting the stack flag 24 (e.g., to 1). Zone B passes in the following third loop. The difference between the value in the counter 21 when zone B passes (i.e., 2) and that in the counter 21 when zone A passes, or the value in the stack register 22 (i.e., 1) is below the threshold (i.e., 2). This determines the to-be-tested page as a pass, and therefore signal WLPass indicative of a pass is output.

FIG. 13 illustrates a case where both zones A and B pass in the same loop count. As shown in FIG. 13, zones A and B pass in the fifth loop. The value in the counter 21 when zones A and B pass (i.e., 4) is stored in the stack register 22, and the stack flag 24 is set. The difference between the loop count when zone A passes and that when zone B passes is below the threshold. This determines the to-be-tested page determined as a pass, and therefore signal WLPass indicative of a pass is output.

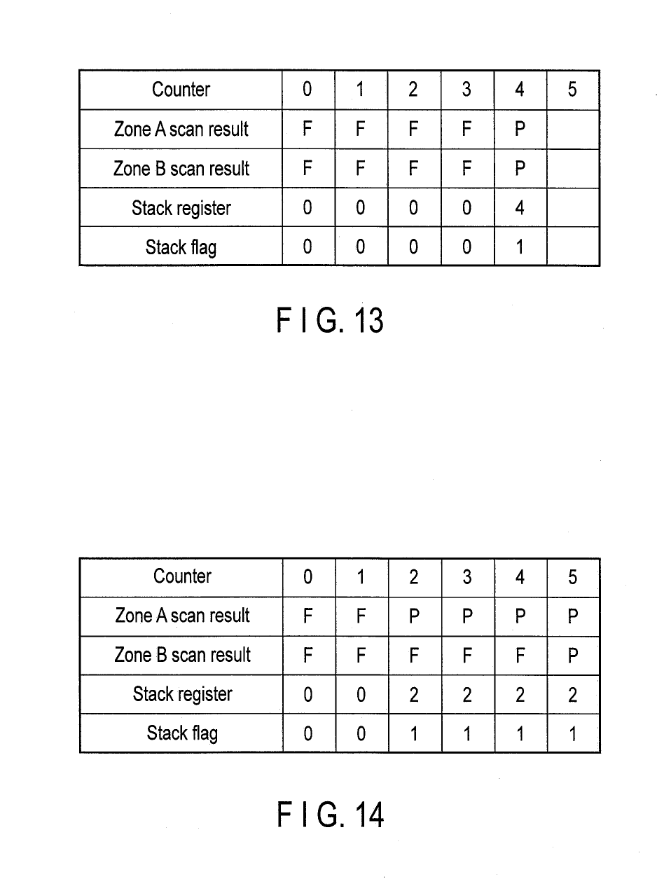

FIG. 14 illustrates a case where both zones A and B pass but the difference between the loop counts for zones A and B to pass exceeds the threshold. As shown in FIG. 14, zone A passes in the third loop and zone B the sixth loop. The difference between the stack register 22 holding the loop count when zone A passes (i.e., 2) and that when zone B passes (i.e. 5) exceeds the threshold. This determines the to-be-tested page as a fail, and therefore signal WLPass indicative of the fail is output.

Note that the conditions of step S21 may be fulfilled when either zone A or B has passed or when none of them has passed but under some circumstance. Such case may be a case with the maximum loop count four, zone A having passed in the third loop, and zone B having reached the maximum loop count. In such a case, even when the conditions of step S21 are fulfilled, the to-be-tested page is determined to be fail only by signal PCMAX being 1.

The conditions of step S21 are fulfilled also when both zones A and B have reached the maximum loop count without having passed. Also in this case, the to-be-tested page is determined to be fail by signal PCMAX being 1. The screening test for the disconnect defect (or, test mode 1) can follow the test for the write defect (or, test mode 0) as described above. This prevents the PCMAX from becoming 1 at the stage of the screening test for the disconnect defect. This can simplify the screening test for the disconnect defect.

As described above, in the semiconductor memory device according to the first embodiment, data is simultaneously written in zones A and B of each page, and the test circuit 14 compares with a threshold the difference between the loop count when zone A passes and that when zone B passes. This consumes a much shorter time for the test than a time taken by an example to perform write and pass-or-fail determination on zones A and B separately. Furthermore, the comparison between the loop counts difference and the threshold is executed by the semiconductor memory device 10, and no signal needs to be output to outside the device. This can further reduce the time for the test.

### Second Embodiment

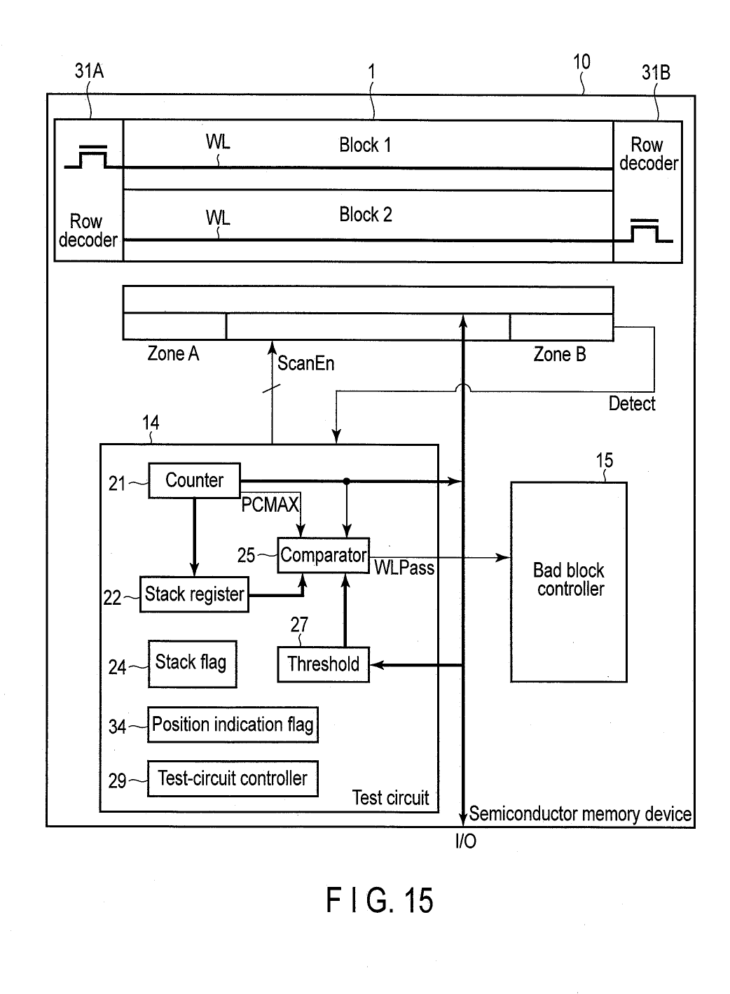

The second embodiment takes which one of the two sides of the memory cell array 1 where the row decoder resides into consideration for the determination. FIG. 15 illustrates a block diagram of part of a semiconductor memory device according to the second embodiment. Specifically, FIG. 15 illustrates part of the semiconductor memory device regarding a screening test to detect memories with disconnect defects. The whole arrangement is the same as that for the first embodiment (FIG. 4). In some cases, the row decoder (or driver), which is part of the word line controller 6, or at least its output unit may be divided to be provided in the opposing sides of the memory cell array 1. For example, blocks are provided with respective row decoders for odd-numbered blocks on a side of the memory cell array 1 and those for even-numbered blocks on the other side of the memory cell array 1. FIG. 15 illustrates such an example. Specifically, the semiconductor memory device 10 includes row decoders 31A and 31B. The row decoder 31A is located on one of the two opposing sides of the memory cell array 1 (the left-hand side in the figure), and the row decoder 31B on the other side (the right-hand side in the figure). The row decoders 31A and 31B are coupled to word lines WL in block 1 and those in block 2, respectively. FIG. 15 illustrates only two blocks and two row decoders for simplification.

A word lines WL with the disconnect defect has a defect somewhere therein. This results in deteriorated performance of write to memory cells beyond the defect when seen from the row decoder, i.e., those on the side opposite the row decoder. With such phenomenon, the second embodiment involves comparing with a threshold a difference obtained by subtracting a loop count when one of zones A and B nearer from the row decoder has passed from that when the farther one has passed.

As shown in FIG. 15, the test circuit 14 further includes a position indication flag holder (position indication flag) 34. The position indication flag 34 is set when a page under test is driven by the row decoder 31A on zone A side and the stack flag 24 is clear upon a pass of detect scan A. The position indication flag 34 is also set when the page under test is driven by the row decoder 31B on zone B side and the stack flag 24 is clear upon a pass of detect scan B. Which row decoder 31A or 31B is driving the page under test can be determined from the address of the page, which in turn is recognized by the test circuit 14 (for example, test-circuit controller 29).

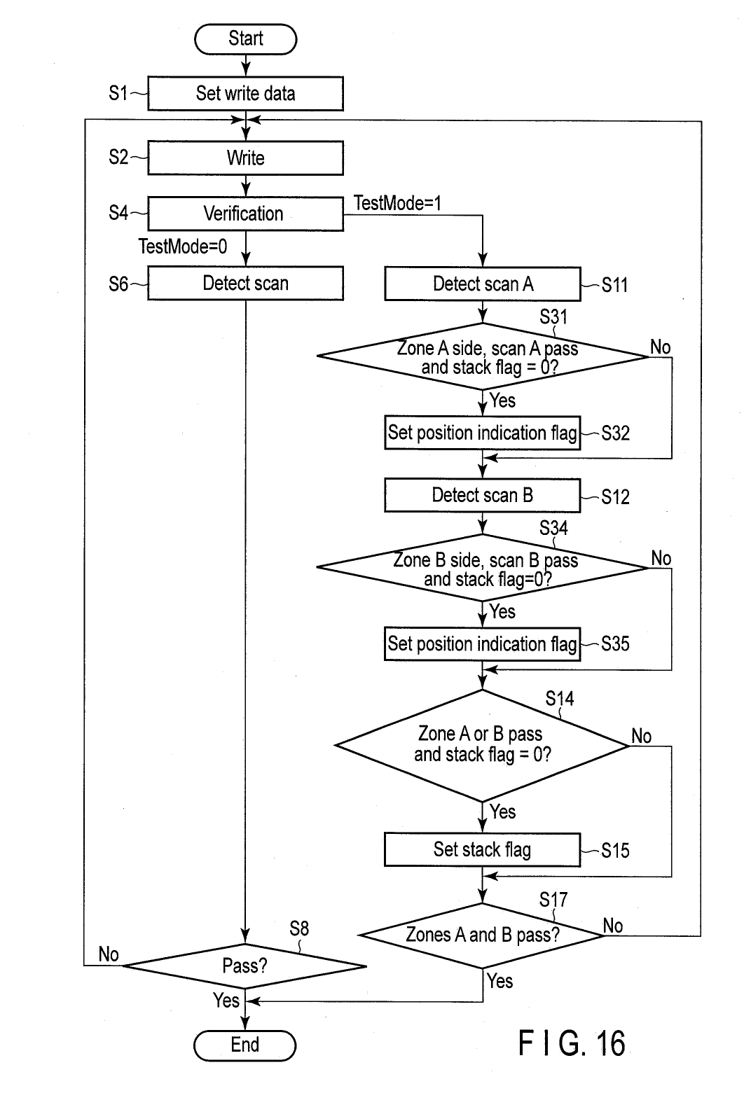

FIG. 16 illustrates part of the flow of a screening test of the semiconductor memory device of the second embodiment. As shown in FIG. 16, step S11 continues to step S31. In step S31, the test-circuit controller 29 determines whether the page under test is driven by the row decoder 31A on zone A side, detect scan A has passed, and the stack flag 24 is clear. When the determination in step S31 is Yes, it may indicate zone A, which is positioned nearer to the row decoder 31A, has passed before zone B. Then, the test-circuit controller 29 sets the position indication flag 34 (step S32). When the determination in step S31 is No, the process shifts to step S12. Step S12 continues to step S34. In step S34, the test-circuit controller 29 determines whether the page under test is driven by the row decoder 31B on zone B side, the detect scan B has passed, and the stack flag 24 is clear. When the determination in step S34 is Yes, it may indicate zone B, which is positioned nearer to the row decoder 31B, has passed before zone A. Then, the test-circuit controller 29 sets the position indication flag 34 (step S35). When the determination in step S34 is No, the process shifts to step S14.

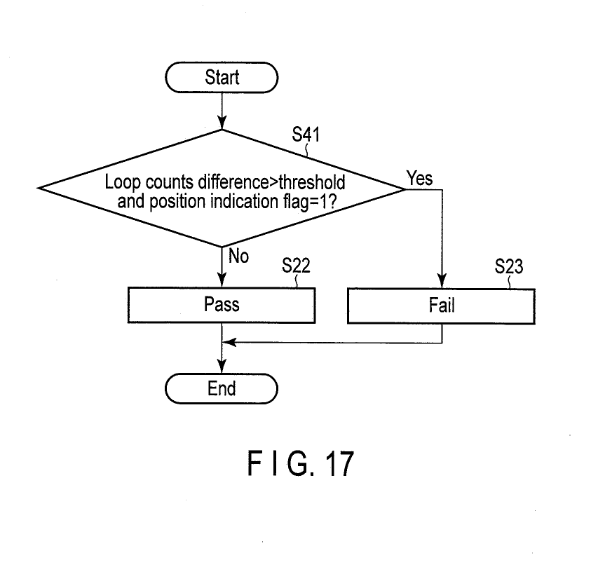

In the test mode 1, the FIG. 16 flow (or write sequence) continues to the FIG. 17 flow. FIG. 17 illustrates part of the flow of the screening test of the semiconductor memory device of the second embodiment.

As shown in FIG. 17, in step S41, the difference between the loop counts when zones A and B passes respectively is compared with a threshold as in step S21. In step S41, the test-circuit controller 29 also determines whether the position indication flag 34 is set. That the position indication flag 34 is set indicates one of zones A and B nearer to the row decoder 31A (or 31B) has passed earlier. Then, in step S41, when the loop count difference exceeds the threshold and the position indication flag 34 is set, it is correctly determined that the page under test has a disconnect defect. Such determination corresponds to comparison with the threshold the difference obtained by subtracting the loop count when one of zones A and B nearer to the row decoder 31A (or 31B) passes from that when the farther one passes. Then, in step S41, when the loop count difference exceeds the threshold and the position indication flag 34 is set, it is correctly determined that the page under test has a disconnect defect. This then shifts the sequence to step S23. Even with the loop count difference exceeding the threshold, when the position indication flag 34 is not set, it is not at least determined that the page with a disconnect defect has been detected. In this case, the process shifts to step S22. However, the pass determination in step S22 indicates a pass determination at least with respect to no detection of a page with a disconnect defect.

As described above, in the semiconductor memory device according to the second embodiment, data is simultaneously written in zones A and B of each page, and the test circuit 14 compares the loop count difference upon pass determination with a threshold as in the first embodiment. This provides the same advantages as those by the first embodiment. Moreover, the second embodiment uses the fact that one of zones A and B nearer to the row decoder 31A (or 31B) has passed earlier than the farther one as a condition to determine whether the page under test has disconnect defect. This can detect pages with disconnect defects more correctly.

Structure of the memory cell array 10 is not limited as above description. A memory cell array formation may be disclosed in U.S. patent application Ser. No. 12/532,030. U.S. patent application Ser. No. 12/532,030, the entire contents of which are incorporated by reference herein.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array comprising memory cells and a word line coupling the memory cells;
a determination circuit configured to determine whether write to a first memory cell group of the word line succeeded, and whether write to a second memory cell group of the word line succeeded, the first memory cell group being different from the second memory cell group; and
a test circuit configured to count application of write voltage during write to the word line, compare with a threshold a difference between a count of write voltage application upon success of one of write to the first memory cell group and write to the second memory cell group and a count of write voltage application upon success of the other of write to the first memory cell group and write to the second memory cell group, and output a result of the comparison.

2. The device of claim 1, wherein the test circuit comprises:
a counter to count application of write voltage to the word line and store the count;
a register to store a count of write voltage application when one of write to the first memory cell group and write to the second memory cell group succeeds earlier; and
a comparator to compare with the threshold a difference between a count of write voltage application upon success of the other of the write to the first memory cell group and the write to the second memory cell group and a value in the register and output the comparison result.

3. The device of claim 2, wherein the determination circuit is configured to:
determine write to the first memory cell group succeeded when write to all memory cells in the first memory cell group succeeded; and
determine write to the second memory cell group succeeded when the writ to all memory cells in the second memory cell group succeeded.

4. The device of claim 3, further comprising a controller configured to repeat write voltage application until both write to the first memory cell group and write to second memory cell groups succeeds.

5. The device of claim 4, wherein the test circuit is configured to:
store a flag indicating one of write to the first memory cell group and write to the second memory cell group succeeded earlier; and
set the flag when the flag is clear upon success of one of write to the first memory cell group and write to the second memory cell group.

6. The device of claim 5, wherein the test circuit is configured to determine whether both write to the first memory cell group and write to the second memory cell group succeeded when the flag is set upon success of one of write to the first memory cell group and write to the second memory cell group.

7. The device of claim 1, further comprising a controller configured to write data in the first and second memory cell groups simultaneously, and read the data of the first and second memory cell groups simultaneously, and wherein
the determination circuit is configured to execute determination in accordance with the read data.

8. The device of claim 1, wherein:
the first memory cell group comprises ones of a series of the memory cells from a first end of the series of memory cells; and
the second memory cell group comprises ones of the series of the memory cells from a second end of the series of memory cells.

9. The device of claim 1, further comprising a controller configured to register a block including the word line as bad when the result indicates the difference exceeds the threshold.

10. The device of claim 1, wherein:
the word line is coupled at a first side or a second side to a decoder driving the word line; and
the test circuit is configured to compare with the threshold a difference obtained by subtracting a count of write voltage application upon success of write to one of the first and second memory cell groups nearer to the decoder from a count of write voltage application upon success of write to the other of the first and second memory cell groups further from the decoder.

11. A method for testing a semiconductor memory device, comprising:
writing data through repeated application of write voltage to memory cells coupled to a word line while counting the write voltage application;
determining whether write to a first memory cell group of the word line succeeded;
determining whether write to a second memory cell group of the word line succeeded, the first memory cell group being different from the second memory cell group;
comparing with a threshold a difference between a count of write voltage application upon success of one of write to the first memory cell group and write to the second memory cell group and a count of write voltage application upon success of the other of write to the first memory cell group and write to the second memory cell group, and output the comparison result; and
outputting a result of the comparison.

12. The method of claim 11, wherein the comparing of a difference with a threshold comprises:
counting application of write voltage to the word line and storing the count;
storing a count of write voltage application when one of write to the first memory cell group and write to the second memory cell group succeeds earlier;
comparing with the threshold a difference between a count of write voltage application upon success of the other of the write to the first memory cell group and the write to the second memory cell group and a value in the register and outputting the comparison result.

13. The method of claim 2, wherein:
the determining of whether write to a first memory cell group succeeded comprises determining write to the first memory cell group succeeded when write to all memory cells in the first memory cell group succeeded; and
the determining of whether write to a second memory cell group succeeded comprises determining write to the second memory cell group succeeded when the writ to all memory cells in the second memory cell group succeeded.

14. The method of claim 13, the writing comprises repeating write voltage application until both write to the first memory cell group and write to second memory cell groups succeeds.

15. The method of claim 14, further comprising:
storing a flag indicating one of write to the first memory cell group and write to the second memory cell group succeeded earlier; and
setting the flag when the flag is clear upon success of one of write to the first memory cell group and write to the second memory cell group.

16. The method of claim 15, further comprising determining whether both write to the first memory cell group and write to the second memory cell group succeeded when the flag is set upon success of one of write to the first memory cell group and write to the second memory cell group.

17. The method of claim 11, wherein:
the writing comprises writing data in the first and second memory cell groups simultaneously;
the method further comprises reading the data of the first and second memory cell groups simultaneously;
the determining of whether write to a first memory cell group succeeded comprises executing that determination in accordance with the read data; and
the determining of whether write to a second memory cell group succeeded comprises executing that determination in accordance with the read data.

18. The method of claim 11, wherein:
the first memory cell group comprises ones of a series of the memory cells from a first end of the series of memory cells; and
the second memory cell group comprises ones of the series of the memory cells from a second end of the series of memory cells.

19. The method of claim 11, further comprising registering a block including the word line as bad when the result indicates the difference exceeds the threshold.

20. The method of claim 11, wherein:
the word line is coupled at a first side or a second side to a decoder driving the word line; and
the comparing comprises comparing with the threshold a difference obtained by subtracting a count of write voltage application upon success of write to one of the first and second memory cell groups nearer to the decoder from a count of write voltage application upon success of write to the other of the first and second memory cell groups further from the decoder.
